(19) United States
(12) Patent Application Publication
(10) Pub. No.: US 2025/0248031 A1
(43) Pub. Date: Jul. 31, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Shih-Yu Liao, Hsinchu (TW); Chung-Liang Cheng, Changhua (TW)

(73) Assignee: Taiwan Semiconductor Manufacturing Company, Ltd., Hsinchu (TW)

(21) Appl. No.: 18/423,745

(22) Filed: Jan. 26, 2024

(51) Int. Cl. H10B 41/30; G11C 16/04; H10B 41/10; H10B 41/35; H10B 43/10; H10B 43/30; H10B 43/35

(52) U.S. Cl. CPC H10B 41/30; G11C 16/0483; H10B 41/10; H10B 41/35; H10B 43/10; H10B 43/30; H10B 43/35

(57) ABSTRACT

A semiconductor fabrication method includes providing a substrate with a logic device formed on the substrate and a plurality of metal routing layers disposed above the logic device and substrate with metal routing connected to the logic device, the plurality of metal routing layers including an upper metal routing layer with metal lines, vias, and a planarized oxide layer; forming a fin structure over the oxide layer in the upper metal routing layer from IGZO; forming a high-K dielectric layer over the oxide layer and the fin structure; forming a storage gate over channel regions of the fin structure; forming a control gate on a first side and a second side of the storage gate; and connecting at least one of the control gate and a source/drain regions of the fin structure to the logic device using VIAs and metal lines.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top view of a portion of an example semiconductor device, in accordance with various embodiments.

FIG. 1B is a cross-sectional view of an example transistor of FIG. 1A along an x-axis, in accordance with various embodiments.

FIG. 1C is a cross-sectional view of an example transistor of FIG. 1A along a y-axis, in accordance with various embodiments.

FIG. 1D is a schematic diagram of an example MTP 4×4 NOR array of FIG. 1A, in accordance with various embodiments.

FIGS. 2A and 2B are cross-sectional diagrams of a portion of an example semiconductor device.

FIG. 3A is a top view of a portion of an example semiconductor device, in accordance with various embodiments.

FIG. 3B is a cross-sectional view of an example transistor of FIG. 3A along an x-axis, in accordance with various embodiments.

FIG. 3C is a cross-sectional view of an example transistor of FIG. 3A along a y-axis, in accordance with various embodiments.

FIG. 3D is a schematic diagram of an example MTP NAND array of FIG. 3A, in accordance with various embodiments.

FIGS. 4A and 4B are cross-sectional diagrams of a portion of an example semiconductor device, in accordance with various embodiments.

FIG. 5 is a flow chart depicting an example method for fabricating a semiconductor device, in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies and may be incorporated into a variety of semiconductor devices and products. Further, it is noted that semiconductor device structures include a varying number of components and that single components shown in the illustrations may be representative of multiple components.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another region, layer, or section. Thus, a first element, component, region, layer, portion, or section discussed below could be termed a second element, component, region, layer, portion, or section without departing from the teachings of the present disclosure.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

In certain embodiments herein, a “material layer” is a layer that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a layer that is a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of an aluminum layer and a layer of aluminum is a layer that is at least 50 wt. %, at least 60 wt. %, at least 75 wt. %, at least 90 wt. %, at least 95 wt. %, or at least 99 wt. % of aluminum.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

Multiple-time programmable (MTP) non-volatile memory (NVM) cells can be formed as NAND devices or NOR devices. Embodiments provided herein provide for forming MTP NVM cells during back end of line (BEOL) processing. Embodiments provided herein provide for increasing the device density of NAND and/or NOR devices in an integrated circuit using BEOL processing. In various embodiments, MTP NVM cells are fabricated in upper metallization layers to increase the density of MTP NVM cells in an integrated circuit. In various embodiments, NAND and/or NOR devices are fabricated in upper metallization layers to increase the device density of NAND and/or NOR devices in an integrated circuit.

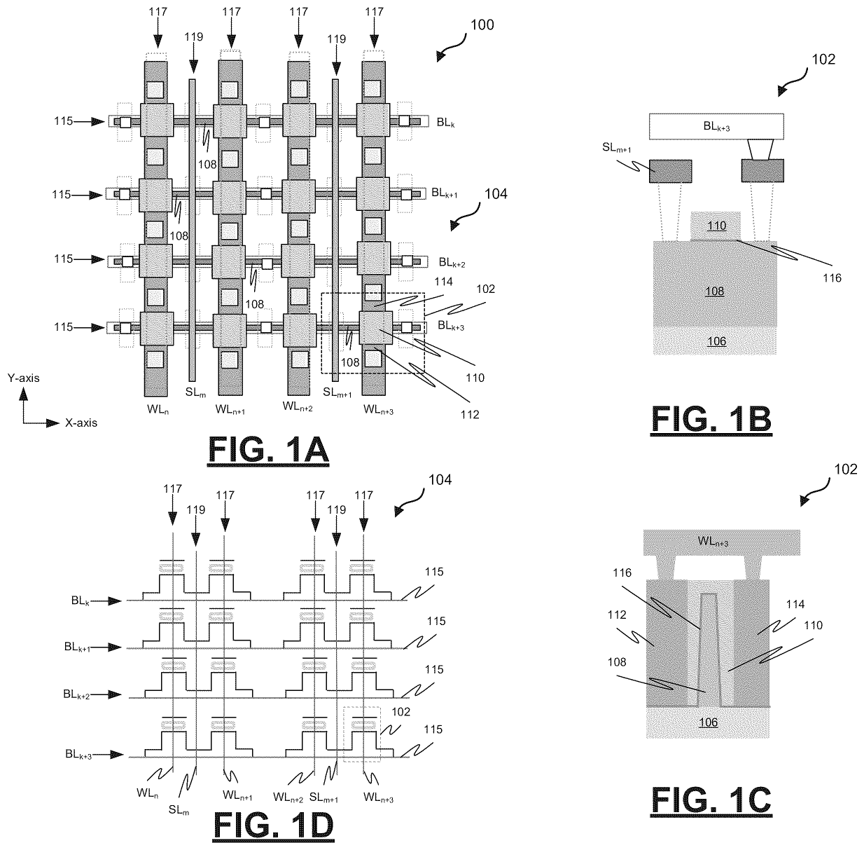

FIG. 1A is a top view of a portion of an example semiconductor device 100, in accordance with various embodiments. The example semiconductor device 100 includes a plurality of FinFET transistors 102 arranged as NOR devices in a MTP 4×4 NOR array 104. FIG. 1B is a cross-sectional view of an example transistor 102 of FIG. 1A along an x-axis, and FIG. 1C is a cross-sectional view of an example transistor 102 of FIG. 1A along a y-axis. FIG. 1D is a schematic diagram of the example MTP 4×4 NOR array 104 of FIG. 1A. Note that for clarity, not all features of the semiconductor device 100 are illustrated in FIGS. 1A, 1B, 1C, and 1D, and FIGS. 1A, 1B, 1C, and 1D may illustrate only a portion of the semiconductor structure formed. The example transistors 102 and the example NOR array 104 are fabricated in upper metallization layers, such as between a metal 5 layer and a metal 6 layer or between a metal 6 layer and a metal 7 layer. The example FinFET transistors 102 include a source and a drain, among other elements. Source/drain region(s) as used herein may refer to a source or a drain, individually or collectively dependent upon the context.

As illustrated in FIGS. 1A, 1B, and 1C, the example FinFET transistors 102 are formed on an oxide layer 106 of a metallization layer and include a fin structure 108 formed over a portion of the oxide layer 106, a storage gate 110 formed over channel regions of the fin structure 108 and a portion of the oxide layer 106 for storing electrons emitted by the fin structure 108, a first control gate 112 formed over the oxide layer 106 and on a first side wall of the storage gate 110, and a second control gate 114 formed over the oxide layer 106 and on a second side wall of the storage gate 110. The example FinFET transistors 102 further includes a high-K dielectric layer 116 disposed between the fin structure 108 and the storage gate 110, between the storage gate 110 and the oxide layer 106, between the first control gate 112 and the oxide layer 106, and between the second control gate 114 and the oxide layer 106.

As illustrated in FIGS. 1A, 1B, 1C, and 1D, in the example NOR array 104, the fin structures 108 of four sets of four series connected FinFET transistors 102 are connected in series in four rows 115. Control gates 112, 114 of the FinFET transistors 102 are connected to form four word line (WL) columns 117. Each WL column 117 is connected to a different WL, each row 115 of fin structures 108 is connected at ends of the row to a different bit line (BL), and source/drain connections between neighboring FinFET transistors 102 in a row 115 of fin structures 108 are alternately connected to a different source line 119 or the bit line for the row 115 of fin structures 108. In this disclosure, a source and a drain are interchangeably used, and the structures thereof are substantially the same.

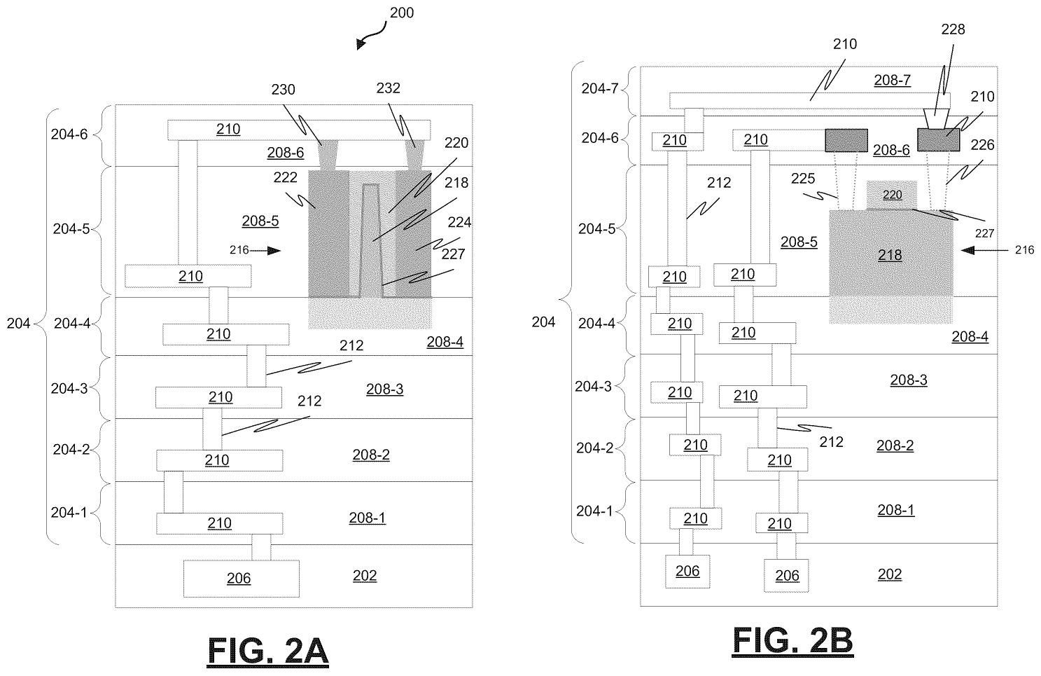

FIGS. 2A and 2B are cross-sectional diagrams of a portion of an example semiconductor device 200. Note that for clarity, not all features of the semiconductor device 200 are illustrated in FIGS. 2A and 2B, and FIGS. 2A and 2B may illustrate only a portion of the semiconductor structure formed. Depicted in FIG. 2A is a cross-sectional view along a y-axis, and FIG. 2B is a cross-sectional view along an x-axis. The example semiconductor device 200 includes a semiconductor substrate 202 and an interconnect structure 204.

The semiconductor substrate 202 may be a semiconductor substrate, such as silicon (si), doped or undoped, or an active layer of a semiconductor-on-insulator (SOI) substrate. The semiconductor substrate may include semiconductor materials such as Si, Ge, Ga, Zn, In, or O. The semiconductor substrate may include other semiconductor materials such as a compound semiconductor including silicon carbide, gallium arsenic, gallium phosphide, gallium nitride, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

The semiconductor substrate 202 can include any number of conductive features and logic device 206 formed in and/or over the semiconductor substrate. Conductive features can include, for example, plugs, interconnects, wiring lines, etc. Logic device 206 can include, for example, transistors, diodes, capacitors, logic devices formed therefrom, etc. For example, the transistors may be metal oxide semiconductor field effect transistors (MOSFETs), complementary metal oxide semiconductor (CMOS) transistors, bipolar junction transistors (BJT), high-voltage transistors, high-frequency transistors, planar FETs such as p-channel field effect transistors (PFETs) or n-channel field effect transistors (NFETs), FinFETs, gate-all-around (GAA) FET devices, or other suitable elements. In various embodiments, a transistor comprises a source, a drain, a gate electrode, a gate dielectric, and a channel. The substrate 202 may further include isolation features (not shown), such as shallow trench isolation (STI) features, deep trench isolation (DTI) features, or local oxidation of silicon (LOCOS) features. The isolation features may define and isolate the various device elements.

The interconnect structure 204 provides routing and electrical connections between logic devices 206 formed in and/or over the substrate 202. The interconnect structure 204 may include a plurality of metallization layers (also referred to herein as metal routing layers)—a first metallization layer 204-1, a second metallization layer 204-2, a third metallization layer 204-3, a fourth metallization layer 204-4, a fifth metallization layer 204-5, a sixth metallization layer 204-6, and a seventh metallization layer 204-7 are shown in the example of FIGS. 2A and 2B.

The example first, second, third, fourth, fifth, sixth, and seventh metallization layers 204-1, 204-2, 204-3, 204-4, 204-5, 204-6, and 204-7, respectively, include a first inter-metal dielectric (IMD) layer 208-1, a second IMD layer 208-2, a third IMD layer 208-3, a fourth IMD layer 208-4, a fifth IMD layer 208-5, a sixth IMD layer 208-6, and a IMD metallization layer 208-7, and may include one or more conductive features, which in this example include metal lines 210 and/or VIAs 212 formed therein in a metallization layer. The conductive features may be electrically connected to active and/or passive devices of the substrate 202 by contacts (not shown in the figures).

In various embodiments, the interconnect structure 204 electrically connects the source, drain, gate electrode, gate dielectric, and/or a channel of a transistor, and other features of the substrate 202 to other features or logic devices 206 on the substrate 202 or within the interconnect structure 204.

In some embodiments, the interconnect structure 204 may be formed using a single and/or a dual damascene process, a VIA-first process, or a metal-first process. In an embodiment, IMD layers (e.g., 208-1, 208-2, 208-3, 208-4, 208-5, 208-6, 208-7) and openings (not shown) may be formed therein using acceptable photolithography, deposition, and etching techniques. The first, second, third, fourth, fifth, sixth, and seventh IMD layers (208-1, 208-2, 208-3, 208-4, 208-5, 208-6, 208-7) may, for example, be or comprise an oxide film, such as silicon oxide, undoped silicon glass (USG), fluorosilicate glass (FSG), boron doped silicate glass (BSG), phosphosilicate glass (PSG), boron phosphorous-doped silicate glass (BPSG), polyethylene oxide (PEOX), thermal oxide, silicon dioxide (SiO₂), or another suitable dielectric material. One or more of the IMD layers (e.g., 208-1, 208-2, 208-3, 208-4, 208-5, 208-6, 208-7) may be made of low dielectric constant (low-k) materials, such as a dielectric constant of less than about 3.0, or less than about 2.5.

Conductive material for the metal lines 210 and/or VIAs 212 may be formed in the openings in the IMD layers from conductive material, such as copper (Cu), aluminum (Al), tungsten (W), nickel (Ni), cobalt (Co), silver (Ag), titanium (Ti), titanium nitride (TiN), gallium (Ga), zinc (Zn), ruthenium (Ru), molybdenum (Mo), indium tin oxide (ITO), combinations thereof, or other applicable materials, and may be formed in the openings using an electro-chemical plating process, chemical vapor deposition (CVD), atomic layer deposition (ALD), physical vapor deposition (PVD), the like, or a combination thereof. After formation of the conductive material, excess conductive material may be removed using, for example, a planarization process such as chemical mechanical polishing (CMP), thereby leaving conductive features in the openings of an insulating layer. The process may then be repeated to form additional insulating layers and conductive features therein. The interconnect structure 204 shown in FIGS. 2A and 2B are merely for illustrative purposes. The interconnect structure 204 may include other configurations and may include one or more metal lines and IMD layers.

An example FinFET transistor 216 is formed on oxide of IMD layer 208-4 of metallization layer 204-4 and includes a fin structure 218 formed over a portion of the IMD layer 208-4, a storage gate 220 formed over channel regions of the fin structure 218 and a portion of the IMD layer 208-4, a first control gate 222 formed over the IMD layer 208-4 and on a first side wall of the storage gate 220, and a second control gate 224 formed over the IMD layer 208-4 and on a second side wall of the storage gate 220. The example FinFET transistors 216 further includes a high-K dielectric layer 227 (e.g., having a dielectric constant greater than about 3.0) disposed between the fin structure 218 and the storage gate 220, between the storage gate 220 and the IMD layer 208-4, between the first control gate 222 and the IMD layer 208-4, and between the second control gate 224 and the IMD layer 208-4.

The example FinFET transistor 216 is formed in a fifth metallization layer 204-5 and forms part of a NOR device that forms a MTP NVM memory cell. In this example, a first source/drain region of the fin structure 218 may be connected to a source line or a source/drain region of another memory cell transistor by a VIA 225 to a metal line 210 in the sixth metallization layer 204-6, a second source/drain region of the fin structure 218 may be connected to a bit line or a source/drain region of another memory cell transistor by a VIA 226 to another metal line 210 in the sixth metallization layer 204-6, which in turn is connected to another metal line 210 in the seventh metallization layer 204-7 by a VIA 228, and the control gate (combination of first control gate 222 and second control gate 224) is connected to a word line by a VIA 230 and a VIA 232 to a metal line 210 in the sixth metallization layer 204-6.

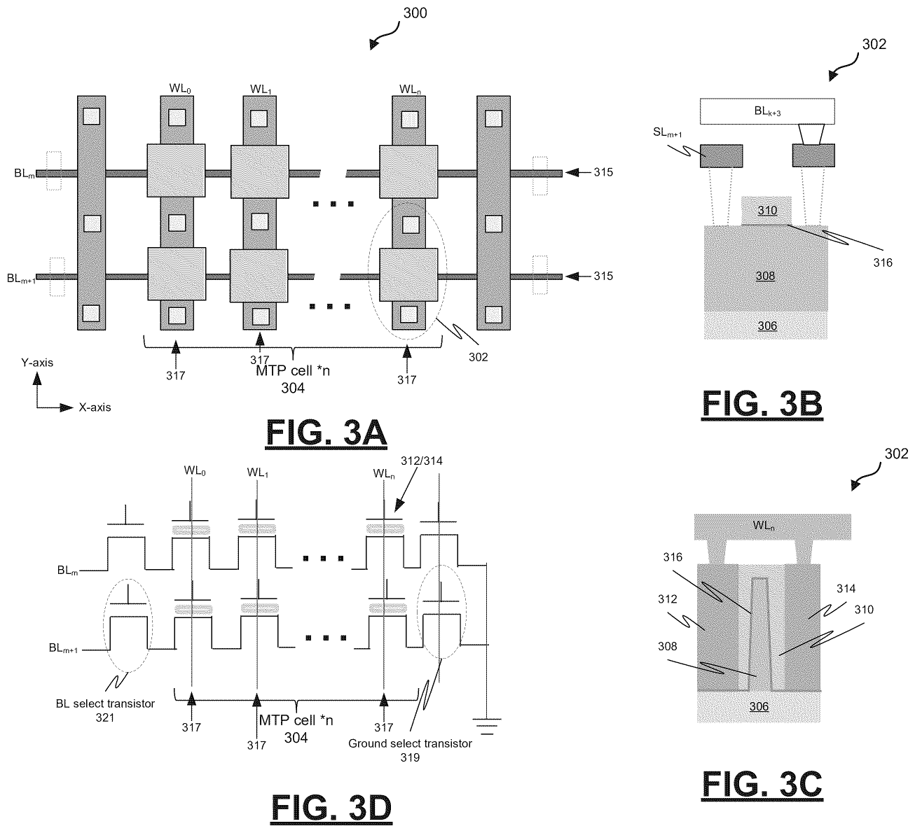

FIG. 3A is a top view of a portion of an example semiconductor device 300, in accordance with various embodiments. The example semiconductor device 300 includes a plurality of FinFET transistors 302 arranged as NAND devices in an MTP NAND array 304. FIG. 3B is a cross-sectional view of an example transistor 302 of FIG. 3A along an x-axis, and FIG. 3C is a cross-sectional view of an example transistor 302 of FIG. 3A along a y-axis. FIG. 3D is a schematic diagram of the example MTP NAND array 304 of FIG. 3A. Note that for clarity, not all features of the semiconductor device 300 are illustrated in FIGS. 3A, 3B, 3C, and 3D, and FIGS. 3A, 3B, 3C, and 3D may illustrate only a portion of the semiconductor structure formed. The example transistors 302 and the example NAND array 304 are fabricated in upper metallization layers, such as between a metal 5 layer and a metal 6 layer or between a metal 6 layer and a metal 7 layer.

As illustrated in FIGS. 3A, 3B, and 3C, the example FinFET transistors 302 are formed on an oxide layer 306 of a metallization layer and include a fin structure 308 formed over a portion of the oxide layer 306, a storage gate 310 formed over channel regions of the fin structure 308 and a portion of the oxide layer 306 for storing electrons emitted by the fin structure 308, a first control gate 312 formed over the oxide layer 306 and on a first side wall of the storage gate 310, and a second control gate 314 formed over the oxide layer 306 and on a second side wall of the storage gate 310. The example FinFET transistors 302 further includes a high-K dielectric layer 316 disposed between the fin structure 308 and the storage gate 310, between the storage gate 310 and the oxide layer 306, between the first control gate 312 and the oxide layer 306, and between the second control gate 314 and the oxide layer 306.

As illustrated in FIGS. 3A, 3B, 3C, and 3D, in the example NAND array 304, the fin structures 308 of two sets of series-connected FinFET transistors 302 are connected in series in two rows 315. Control gates 312, 314 of the FinFET transistors 302 are connected to form word line (WL) columns 317. Each WL column 317 is connected to a different WL, each row 315 of fin structures 308 are connected at one end of the row to a different bit line (BL) and at another end to a ground select transistor 319, and source/drain connections between neighboring FinFET transistors 302 in a row 315 of fin structures 308 are connected to each other. A bit line select transistor 321 (e.g., formed between metal routing layers or on the substrate) is connected between a bit line and a first of the plurality of MTP NVM memory cells (e.g., FinFET transistor 302) and a ground select transistor 319 (e.g., formed between the metal routing layers or on the substrate) is connected between a ground source and a second of the plurality of MTP NVM memory cells (e.g., FinFET transistor 302).

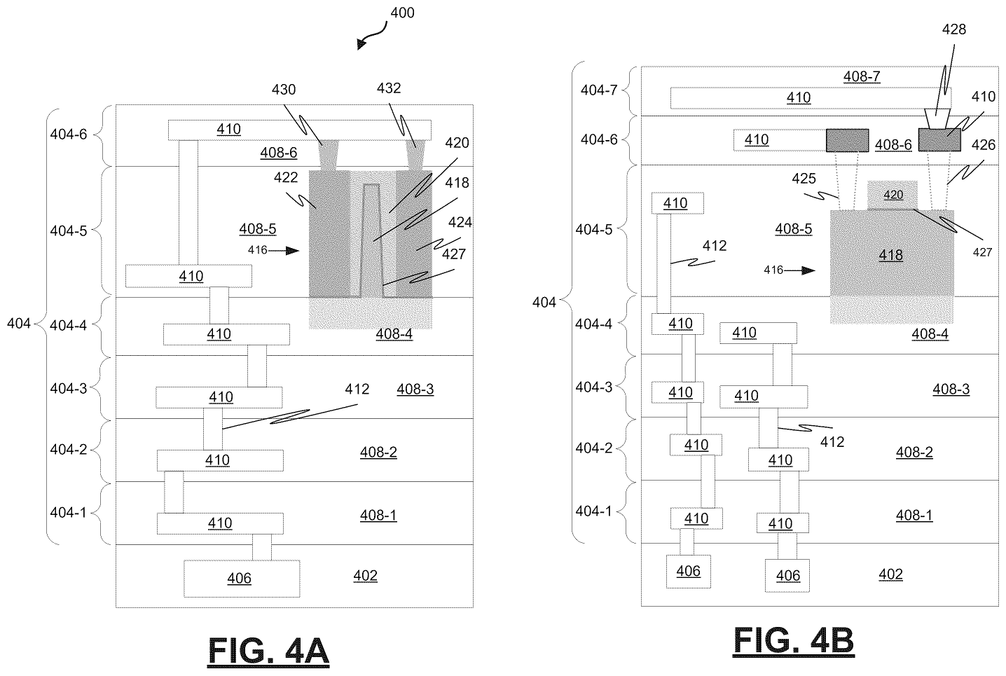

FIGS. 4A and 4B are cross-sectional diagrams of a portion of an example semiconductor device 400. Note that for clarity, not all features of the semiconductor device 400 are illustrated in FIGS. 4A and 4B, and FIGS. 4A and 4B may illustrate only a portion of the semiconductor structure formed. Depicted in FIG. 4A is a cross-sectional view along a y-axis, and FIG. 4B is a cross-sectional view along an x-axis. The example semiconductor device 400 includes a semiconductor substrate 402 and an interconnect structure 404.

The semiconductor substrate 402 may be a semiconductor substrate, such as silicon, doped or undoped, or an active layer of a semiconductor-on-insulator (SOI) substrate. The semiconductor substrate may include other semiconductor materials, such as germanium; a compound semiconductor including silicon carbide, gallium arsenic, gallium phosphide, gallium nitride, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

The semiconductor substrate 402 can include any number of conductive features and logic devices 406 formed in and/or over the semiconductor substrate. Conductive features can include, for example, plugs, interconnects, wiring lines, etc. Logic devices 406 can include, for example, transistors, diodes, capacitors, etc. For example, the transistors may be metal oxide semiconductor field effect transistors (MOSFETs), complementary metal oxide semiconductor (CMOS) transistors, bipolar junction transistors (BJT), high-voltage transistors, high-frequency transistors, planar FETs such as p-channel field effect transistors (PFETs) or n-channel field effect transistors (NFETs), FinFETs, gate-all-around (GAA) FET devices, or other suitable elements. In various embodiments, a transistor comprises a source, a drain, a gate electrode, a gate dielectric, and a channel. The substrate 402 may further include isolation features (not shown), such as shallow trench isolation (STI) features, deep trench isolation (DTI) features, or local oxidation of silicon (LOCOS) features. The isolation features may define and isolate the various device elements.

The interconnect structure 404 provides routing and electrical connections between logic devices 406 formed in and/or over the substrate 402. The interconnect structure 404 may include a plurality of metallization layers (also referred to herein as metal routing layers)—a first metallization layer 404-1, a second metallization layer 404-2, a third metallization layer 404-3, a fourth metallization layer 404-4, a fifth metallization layer 404-5, a sixth metallization layer 404-6, and a seventh metallization layer 404-7 are shown in the example of FIGS. 4A and 4B.

The example first, second, third, fourth, fifth, sixth, and seventh metallization layers 404-1, 404-2, 404-3, 404-4, 404-5, 404-6, and 404-7, respectively, include a first inter-metal dielectric (IMD) layer 408-1, a second IMD layer 408-2, a third IMD layer 408-3, a fourth IMD layer 408-4, a fifth IMD layer 408-5, a sixth IMD layer 408-6, and a IMD metallization layer 408-7, and may include one or more conductive features, which in this example include metal lines 410 and/or VIAs 412 formed therein in a metallization layer. The conductive features may be electrically connected to active and/or passive devices of the substrate 402 by contacts (not shown in the figures).

In various embodiments, the interconnect structure 404 electrically connects the source, drain, gate electrode, gate dielectric, and/or a channel of a transistor, and other features of the substrate 402 to other features or logic devices 406 on the substrate 402 or within the interconnect structure 404.

In some embodiments, the interconnect structure 404 may be formed using a single and/or a dual damascene process, a VIA-first process, or a metal-first process. In an embodiment, IMD layers (e.g., 408-1, 408-2, 408-3, 408-4, 408-5, 408-6, 408-7) and openings (not shown) may be formed therein using acceptable photolithography, deposition, and etching techniques. The first, second, third, fourth, fifth, sixth, and seventh IMD layers (408-1, 408-2, 408-3, 408-4, 408-5, 408-6, 408-7) may, for example, be or comprise an oxide film, such as silicon oxide, undoped silicon glass (USG), fluorosilicate glass (FSG), boron doped silicate glass (BSG), phosphosilicate glass (PSG), boron phosphorous-doped silicate glass (BPSG), polyethylene oxide (PEOX), thermal oxide, silicon dioxide (SiO₂), or another suitable dielectric material. One or more of the IMD layers (e.g., 408-1, 408-2, 408-3, 408-4, 408-5, 408-6, 208-7) may be made of low dielectric constant (low-k) materials, such as a dielectric constant of less than about 3.0, or less than about 2.5.

Conductive material for the metal lines 410 and/or VIAs 412 may be formed in the openings in the IMD layers from conductive material, such as copper (Cu), aluminum (Al), tungsten (W), nickel (Ni), cobalt (Co), silver (Ag), titanium (Ti), titanium nitride (TiN), gallium (Ga), zinc (Zn), ruthenium (Ru), molybdenum (Mo), indium tin oxide (ITO), combinations thereof, or other applicable materials, and may be formed in the openings using an electro-chemical plating process, chemical vapor deposition (CVD), atomic layer deposition (ALD), physical vapor deposition (PVD), the like, or a combination thereof. After formation of the conductive material, excess conductive material may be removed using, for example, a planarization process such as chemical mechanical polishing (CMP), thereby leaving conductive features in the openings of an insulating layer. The process may then be repeated to form additional insulating layers and conductive features therein. The interconnect structure 404 shown in FIGS. 4A and 4B are merely for illustrative purposes. The interconnect structure 404 may include other configurations and may include one or more metal lines and IMD layers.

An example FinFET transistor 416 is formed on oxide of IMD layer 408-4 of metallization layer 404-4 and includes a fin structure 418 formed over a portion of the IMD layer 408-4, a storage gate 420 formed over channel regions of the fin structure 418 and a portion of the IMD layer 408-4, a first control gate 422 formed over the IMD layer 408-4 and on a first side wall of the storage gate 420, and a second control gate 424 formed over the IMD layer 408-4 and on a second side wall of the storage gate 420. The example FinFET transistors 416 further includes a high-K dielectric layer 427 (e.g., having a dielectric constant greater than about 3.0) disposed between the fin structure 418 and the storage gate 420, between the storage gate 420 and the IMD layer 408-4, between the first control gate 422 and the IMD layer 408-4, and between the second control gate 424 and the IMD layer 408-4.

The example FinFET transistor 416 is formed in a fifth metallization layer 404-5 and forms part of a NAND device that forms a MTP NVM memory cell. In this example, a first source/drain region of the fin structure 418 may be connected to a source/drain region of a BL select transistor or a source/drain region of another memory cell transistor by a VIA 425 to a metal line 410 in the sixth metallization layer 404-6, a second source/drain region of the fin structure 418 may be connected to a source/drain region of a ground select transistor or a source/drain region of another memory cell transistor by a VIA 426 to another metal line 410 in the sixth metallization layer 404-6, which in turn is connected to another metal line 410 in the seventh metallization layer 404-7 by a VIA 428, and the control gate (combination of first control gate 422 and second control gate 424) is connected to a word line by a VIA 430 and a VIA 432 to a metal line 410 in the sixth metallization layer 404-6. In various embodiments, at least one of the control gate 422/424 and source/drain regions of the fin structure 418 is connected to a logic device 406.

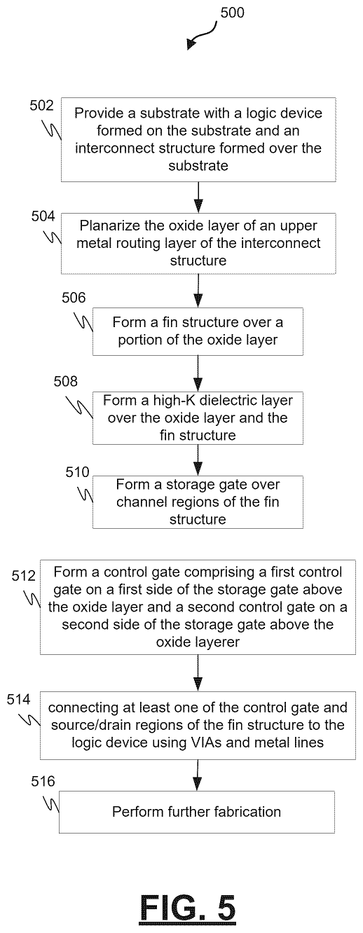

FIG. 5 is a flow chart depicting an example method 500 for fabricating a semiconductor device. FIGS. 1B-1C and FIGS. 2A-2B are cross referenced to provide example embodiments after completion of various blocks of the example method 500.

The example method 500 includes, at block 502, providing a substrate with a logic device formed on the substrate and an interconnect structure formed over the substrate. In various embodiments, the interconnect structure comprises a plurality of metal routing layers disposed above the substrate with metal routing connected to the logic device. In various embodiments, the plurality of metal routing layers include an upper metal routing layer with metal lines, VIAs, and an oxide layer. With reference to FIGS. 1B-1C, and FIGS. 2A-2B, in an example embodiment of block 502, a substrate 202 with a logic device 206 formed on the substrate and an interconnect structure 204 with a plurality of metal routing layers (e.g., metallization layers 204-1, 204-2, 204-3, 204-4, 204-5, 204-6, 204-7) disposed above the substrate is provided. The metal routing layers (e.g., metallization layers 204-1, 204-2, 204-3, 204-4, 204-5, 204-6, 204-7) include metal lines 210 and VIAs 212 connected to the logic device 206. The plurality of metal routing layers (e.g., metallization layers 204-1, 204-2, 204-3, 204-4, 204-5, 204-6, 204-7) include an upper metal routing layer 204-4 with metal lines 210, VIAs 212, and an oxide layer 208-4. In various embodiments, the logic device 206 comprises a transistor device, such as a planar FET, FinFET, or GAA FET device. In various embodiments, the logic device comprises a gate dielectric (e.g., HfO₂ SiO₂, HfO, HfO₂, La, SiON, SiCON, Zn, Zr, etc.), a gate electrode (e.g., Poly-Si, Si, Ti, Ta, Al, W, N, Zn, In, Ga, Ge, C, etc.), a source electrode and a drain electrode (wherein the source/drain comprises Si, Ge, C, P, B, etc.), and a nanosheet channel (e.g., Si). In various embodiments, the substrate comprises Si, Ge, Ga, Zn, In, or O. In various embodiments, the substrate comprises a logic device isolation structure. In various embodiments, the logic device isolation structure in the substrate comprises local oxidation of silicon (LOCOS), shallow trench isolation (STI), deep trench isolation (DTI).

At block 504, the example method 500 includes planarizing the oxide layer of an upper metal routing layer of the interconnect structure. In various embodiments, the planarizing the oxide layer is performed using CMP operations. With reference to FIGS. 1B-1C, and FIGS. 2A-2B, in an example embodiment of block 504, the oxide layer 106/208-4 has been planarized. In some embodiments, the oxide layer may be referred to as an interlayer dielectric (ILD) layer. In some embodiments, the material of the oxide layer includes silicon oxide, silicon nitride, silicon oxynitride, phosphosilicate glass (PSG), borosilicate glass (BSG), boron-doped phosphosilicate glass (BPSG), or low-k materials. The dielectric layer may be formed by any acceptable deposition process, such as spin coating, chemical vapor deposition (CVD), or other suitable methods.

At block 506, the example method 500 includes forming a fin structure over a portion of the oxide layer. In various embodiments, forming a fin structure includes depositing an IGZO layer. Indium gallium zinc oxide (IGZO) is a semiconducting material, consisting of indium (In), gallium (Ga), zinc (Zn) and oxygen (O). By using IGZO, the fin can be formed at a temperature below 400° C. In various embodiments, the IGZO is deposited by ALD or PVD. In various embodiments, after depositing the IGZO, the deposited IGZO is formed in a fin structure. In various embodiments, the fin structure is formed by photolithography, patterning, and etching techniques to cut and etch the IGZO layer into a fin structure. With reference to FIGS. 1B-1C, and FIGS. 2A-2B, in an example embodiment of block 506, a fin structure 108/218 is formed over a portion of the oxide layer 106/208-4.

At block 508, the example method 500 includes forming a high-K dielectric layer over the oxide layer and the fin structure. In various embodiments, the high-K dielectric layer is formed over the oxide layer and the fin structure by a deposition process such as ALD. In various embodiments, the high-K dielectric comprises Hafnium oxide (HfO₂). With reference to FIGS. 1B-1C, and FIGS. 2A-2B, in an example embodiment of block 508, a high-K dielectric layer 116/227 is formed over the oxide layer 106/208-4 and the fin structure 108/218.

At block 510, the example method 500 includes forming a storage gate over channel regions of the fin structure. In various embodiments, the storage gate is a nitride storage gate formed from Silicon nitride (SiN). In various embodiments, the storage gate is a nitride storage gate formed from Titanium nitride (TiN). In various embodiments, the storage gate is formed from TiN and SiN. In various embodiments, the storage gate is formed by a deposition process, such as CVD or PVD. With reference to FIGS. 1B-1C, and FIGS. 2A-2B, in an example embodiment of block 510, a storage gate 110/220 is formed over channel regions of the fin structure 108/218.

At block 512, the example method 500 includes forming a control gate comprising a first control gate on a first side of the storage gate above the oxide layer and a second control gate on a second side of the storage gate above the oxide layer. In various embodiments, forming a control gate comprises depositing a control gate material layer over and around the storage gate using a suitable deposition technique and planarizing the control gate material layer, for example using CMP, to separate the first control gate from the second control gate. In various embodiments, the control gate is formed from a nitride such as, Titanium nitride (TiN) or Tantalum nitride (TaN). In various embodiments, the control gate is formed from Poly-Si, Si, Ti, Ta, Al, W, N, Zn, In, Ga, Ge, or C. With reference to FIGS. 1B-1C, and FIGS. 2A-2B, in an example embodiment of block 512, formed a control gate comprising a first control gate 112/222 formed on a first side of the storage gate 110/220 above the oxide layer 106/208-4 and a second control gate 114/224 formed on a second side of the storage gate 110/220 above the oxide layer 106/208-4.

At block 514, the example method 500 includes connecting at least one of the control gate and source/drain regions of the fin structure to the logic device using VIAs and metal lines. In various embodiments, connecting the at least one of the control gate and source/drain regions of the fin structure to the logic device using VIAs and metal lines includes depositing an IMD oxide layer over the fin structure, control gate, and storage gate, patterning and etching the IMD oxide layer to cut openings for VIAs and metal lines to connect to the at least one of the control gate and source/drain regions of the fin structure, and depositing a metal layer for the VIAs and metal lines. In some embodiments, the material of the VIAs and metal lines may include a metal, such as copper, titanium, tungsten, aluminum, or a combination thereof. The VIAs and metal lines may be formed by CVD or plating. With reference to FIG. 2A, in an example embodiment of block 514, the control gate is connected by a VIA 230 and a VIA 232 through metal lines 210 and VIAs 212 to a logic device 206. With reference to FIG. 2B, in an example embodiment of block 514, a first source/drain region of fin structure 218 is connected by VIA 225 through metal lines 210 and VIAs 212 to a logic device 206, and a second source/drain region of fin structure 218 is connected by VIA 226 through metal lines 210 and VIAs 212 to a logic device 206.

The method 500 may include, at block 516, further processing steps to complete an integrated circuit. Further processing steps may include forming further interconnections between various elements of the semiconductor device. In various embodiments, the method 500 may include forming connections to form NOR devices. In various embodiments, the method 500 may include forming connections to form NAND devices. In various embodiments, the method 500 may include connecting a first source/drain region of the fin structure to a source line, a second source/drain region of the fin structure to a bit line, and the control gate to a word line. In various embodiments, the method 500 may include connecting: a first source/drain region of the fin structure to a source/drain region of a first series-connected transistor, a second source/drain region of the fin structure to a source/drain region of a second series-connected transistor, and the control gate to a word line.

In some aspects, the techniques described herein relate to a semiconductor device including: a substrate with a logic device formed on the substrate; a plurality of metal routing layers disposed above the substrate with metal routing connected to the logic device; and a plurality of multiple-time programmable (MTP) non-volatile memory (NVM) cells formed between the plurality of metal routing layers, the plurality of memory cells including a FinFET transistor having a fin structure, a storage gate disposed around channel regions of the fin structure for storing electrons emitted by the fin structure, and a control gate formed around side walls of the storage gate.

In some aspects, the techniques described herein relate to a device, wherein the plurality of memory cells are formed in a BEOL (back-end-of-line) process.

In some aspects, the techniques described herein relate to a device, wherein the plurality of memory cells include a NOR device.

In some aspects, the techniques described herein relate to a device, wherein a first source/drain region of the fin structure is connected to a source line, a second source/drain region of the fin structure is connected to a bit line, and the control gate is connected to a word line.

In some aspects, the techniques described herein relate to a device, wherein the plurality of memory cells include a NAND device.

In some aspects, the techniques described herein relate to a device, wherein a first source/drain region of the fin structure is connected to a source/drain region of a first series-connected transistor (e.g., formed between the plurality of metal routing layers), a second source/drain region of the fin structure is connected to a source/drain region of a second series-connected transistor (e.g., formed between the plurality of metal routing layers), and the control gate is connected to a word line.

In some aspects, the techniques described herein relate to a device, further including a bit line select transistor (e.g., formed between the plurality of metal routing layers or on the substrate) connected between a bit line and a first of the plurality of memory cells, and a ground select transistor (e.g., formed between the plurality of metal routing layers or on the substrate) connected between a ground source and a second of the plurality of memory cells.

In some aspects, the techniques described herein relate to a device, wherein the fin structure is formed from Indium gallium zinc oxide (IGZO).

In some aspects, the techniques described herein relate to a device, wherein the storage gate is formed from Silicon nitride (SiN).

In some aspects, the techniques described herein relate to a device, wherein the control gate is formed from Titanium nitride (TIN).

In some aspects, the techniques described herein relate to a device, further including a high-K dielectric (e.g., Hafnium oxide (HfO₂)) formed between the storage gate and the fin structure.

In some aspects, the techniques described herein relate to a device, wherein the logic device includes a gate dielectric (e.g., SiO₂, HfO, La, SiON, SiCON, Zn, Zr), a gate electrode (e.g., Poly-Si, Si, Ti, Ta, Al, W, N, Zn, In, Ga, Ge, C), a source electrode, a drain electrode, (e.g., source/drain include of Si, Ge, C, P, B) and a nanosheet channel (e.g., Si).

In some aspects, the techniques described herein relate to a device, wherein the substrate includes Si, Ge, Ga, Zn, In, or O.

In some aspects, the techniques described herein relate to a device, wherein logic device isolation structure in the substrate includes local oxidation of silicon (LOCOS), shallow trench isolation (STI), deep trench isolation (DTI).

In some aspects, the techniques described herein relate to a device, wherein the logic device includes a planar FET, FinFET, or gate all around (GAA) FET device.

In some aspects, the techniques described herein relate to a semiconductor fabrication method including: providing a substrate with a logic device formed on the substrate and a plurality of metal routing layers disposed above the logic device and substrate with metal routing connected to the logic device, the plurality of metal routing layers including an upper metal routing layer with metal lines, vias, and a planarized oxide layer; forming a fin structure over the oxide layer in the upper metal routing layer from IGZO; forming a high-K dielectric layer over the oxide layer and the fin structure; forming a storage gate over channel regions of the fin structure; forming a control gate on a first side and a second side of the storage gate; and connecting at least one of the control gate and a source/drain regions of the fin structure to the logic device using VIAs and metal lines.

In some aspects, the techniques described herein relate to a method, wherein forming the fin structure over the oxide layer in the upper metal routing layer from IGZO includes depositing an IGZO layer by ALD or PVD and forming the deposited IGZO layer into a fin structure by photolithography patterning and etching techniques.

In some aspects, the techniques described herein relate to a method, wherein forming the high-K dielectric layer over the oxide layer and the fin structure includes depositing the high-K dielectric layer by ALD and wherein the high-K dielectric layer includes Hafnium oxide (HfO₂).

In some aspects, the techniques described herein relate to a method, wherein forming the storage gate includes forming a nitride storage gate from Silicon nitride (SiN) by CVD or PVD.

In some aspects, the techniques described herein relate to a method, wherein forming the control gate includes depositing a control gate material layer from Titanium nitride (TiN) or Tantalum nitride (TaN)) over and around the storage gate and planarizing the control gate material layer using CMP to separate a first control gate from a second control gate.

In some aspects, the techniques described herein relate to a method, further including connecting a first source/drain region of the fin structure to a source line, a second source/drain region of the fin structure to a bit line, and the control gate to a word line.

In some aspects, the techniques described herein relate to a method, further including connecting a first source/drain region of the fin structure to a source/drain region of a first series-connected transistor (e.g., formed between the plurality of metal routing layers), a second source/drain region of the fin structure to a source/drain region of a second series-connected transistor (e.g., formed between the plurality of metal routing layers), and the control gate to a word line.

In some aspects, the techniques described herein relate to a memory device including: a logic device; a plurality of metal routing layers with metal routing connected to the logic device; and a multiple-time programmable (MTP) non-volatile memory (NVM) cell formed in a BEOL (back-end-of-line) process between the plurality of metal routing layers, the memory cell including a FinFET transistor having an IGZO (Indium gallium zinc oxide) fin, a storage gate disposed around channel regions of the IGZO fin, and a control gate formed around side walls of the storage gate.

In some aspects, the techniques described herein relate to a memory device, wherein the memory cell is connected to a plurality of other memory cells to form a NOR device.

In some aspects, the techniques described herein relate to a memory device, wherein the memory cell is connected to a plurality of other memory cells to form a NAND device.

In some aspects, the techniques described herein relate to a memory device, wherein the storage gate is formed from Silicon nitride (SiN).

In some aspects, the techniques described herein relate to a memory device, wherein the control gate is formed from Titanium nitride (TiN).

In some aspects, the techniques described herein relate to a memory device, further including a high-K dielectric (e.g., Hafnium oxide (HfO₂)) formed between the storage gate and the IGZO fin.

In some aspects, the techniques described herein relate to a memory device, wherein the logic device includes a gate dielectric (e.g., SiO₂, HfO, La, SiON, SiCON, Zn, Zr), a gate electrode (e.g., Poly-Si, Si, Ti, Ta, Al, W, N, Zn, In, Ga, Ge, C), a source electrode, a drain electrode, (e.g., source/drain include of Si, Ge, C, P, B) and a nanosheet channel (e.g., Si).

In some aspects, the techniques described herein relate to a memory device, wherein the logic device includes a planar FET, FinFET, or gate all around (GAA) FET device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a substrate with a logic device formed on the substrate;
a plurality of metal routing layers disposed above the substrate with metal routing connected to the logic device; and
a plurality of multiple-time programmable (MTP) non-volatile memory (NVM) cells formed between the plurality of metal routing layers, the plurality of memory cells comprising a FinFET transistor having a fin structure, a storage gate disposed around channel regions of the fin structure, and a control gate formed around side walls of the storage gate.

2. The device of claim 1, wherein the plurality of memory cells comprise a NOR device.

3. The device of claim 1, wherein a first source/drain region of the fin structure is connected to a source line, a second source/drain region of the fin structure is connected to a bit line, and the control gate is connected to a word line.

4. The device of claim 1, wherein the plurality of memory cells comprise a NAND device.

5. The device of claim 1, wherein a first source/drain region of the fin structure is connected to a source/drain region of a first series-connected transistor, a second source/drain region of the fin structure is connected to a source/drain region of a second series-connected transistor, and the control gate is connected to a word line.

6. The device of claim 1, wherein the fin structure is formed from Indium gallium zinc oxide (IGZO).

7. The device of claim 1, wherein the storage gate is formed from Silicon nitride (SiN) and the control gate is formed from Titanium nitride (TiN).

8. The device of claim 1, further comprising a high-K dielectric (e.g., Hafnium oxide (HfO₂)) formed between the storage gate and the fin structure.

9. A semiconductor fabrication method comprising:
providing a substrate with a logic device formed on the substrate and a plurality of metal routing layers disposed above the logic device and substrate with metal routing connected to the logic device, the plurality of metal routing layers including an upper metal routing layer with metal lines, vias, and a planarized oxide layer;
forming a fin structure over the oxide layer in the upper metal routing layer from IGZO;
forming a high-K dielectric layer over the oxide layer and the fin structure;
forming a storage gate over channel regions of the fin structure;
forming a control gate on a first side and a second side of the storage gate; and
connecting at least one of the control gate and a source/drain regions of the fin structure to the logic device using VIAs and metal lines.

10. The method of claim 9, wherein forming the fin structure over the oxide layer in the upper metal routing layer from IGZO comprises depositing an IGZO layer by atomic layer deposition (ALD) or physical vapor deposition (PVD) and forming the deposited IGZO layer into a fin structure by patterning and etching techniques.

11. The method of claim 9, wherein forming the high-K dielectric layer over the oxide layer and the fin structure comprises depositing the high-K dielectric layer by atomic layer deposition (ALD) and wherein the high-K dielectric layer comprises Hafnium oxide (HfO₂).

12. The method of claim 9, wherein forming the storage gate comprises forming a nitride storage gate from Silicon nitride (SiN) by chemical vapor deposition (CVD) or physical vapor deposition (PVD).

13. The method of claim 9, wherein forming the control gate comprises depositing a control gate material layer from Titanium nitride (TiN) or Tantalum nitride (TaN)) over and around the storage gate and planarizing the control gate material layer using CMP to separate a first control gate from a second control gate.

14. The method of claim 9, further comprising connecting a first source/drain region of the fin structure to a source line, a second source/drain region of the fin structure to a bit line, and the control gate to a word line.

15. The method of claim 9, further comprising connecting a first source/drain region of the fin structure to a source/drain region of a first series-connected transistor, a second source/drain region of the fin structure to a source/drain region of a second series-connected transistor, and the control gate to a word line.

16. A memory device comprising:
a logic device;
a plurality of metal routing layers with metal routing connected to the logic device; and
a multiple-time programmable (MTP) non-volatile memory (NVM) cell between the plurality of metal routing layers, the memory cell comprising a FinFET transistor having an IGZO (Indium gallium zinc oxide) fin, a storage gate disposed around channel regions of the IGZO fin, and a control gate formed around side walls of the storage gate.

17. The memory device of claim 16, wherein the memory cell is connected to a plurality of other memory cells to form a NOR device.

18. The memory device of claim 16, wherein the memory cell is connected to a plurality of other memory cells to form a NAND device.

19. The memory device of claim 16, further comprising a high-K dielectric formed between the storage gate and the IGZO fin.

20. The memory device of claim 16, wherein the logic device comprises a planar FET, FinFET, or gate all around (GAA) FET device.
